(19) United States
(12) Patent Application Publication
(10) Pub. No.: US 2025/0006659 A1
(43) Pub. Date: Jan. 2, 2025

(54) METHODS AND STRUCTURE FOR REDUCED WARPAGE AND IMPROVED ACOUSTIC SCANNING

(71) Applicant: Taiwan Semiconductor Manufacturing Company LTD, Hsinchu (TW)

(72) Inventors: Ji-Feng Ying, Hsinchu (TW); Xuewen Tang, Hsinchu (TW); Wen-Hsien Chuang, Taipei (TW); Jyun-Lin Wu, Hsinchu (TW); Chia Wei Chang, Taipei (TW)

(21) Appl. No.: 18/216,829

(22) Filed: Jun. 30, 2023

(51) Int. Cl. H01L 23/00; H01L 21/66; H01L 21/71

(52) U.S. Cl. CPC H01L 23/562; H01L 21/71; H01L 22/12; H01L 24/08; H01L 2224/08145

(57) ABSTRACT

Methods for reducing warpage and increasing the effectiveness of hybrid bond void testing are disclosed. A semiconductor package has a first side and a second side, with a dummy bond pad located on the second side, and at least one metal-containing layer between the first side and the second side (for example a redistribution layer). A warpage control structure is provided in the semiconductor package that extends from the first side into the semiconductor package, and is aligned with the dummy bond pad. The warpage control structure is made of a low-density filling. This relieves stress that causes/increases warpage. When a hybrid bond is formed between the semiconductor package and another semiconductor package, the warpage control structure maximizes acoustic wave penetration for testing the quality of the hybrid bond at the dummy bond pad.

### BACKGROUND

Semiconductor packages containing integrated circuits are becoming increasingly complex. For example, System on Integrated Chip (SoIC) has been developed to include a plurality of device dies such as processors and memory cubes which are stacked vertically and interconnected. The device dies can be formed using different technologies and have different functions, and can be heterogeneously combined to obtain desired functionality, thus forming a system which is combined in one chip carrier package. This reduces manufacturing costs and optimizes device performance. Similar three-dimensional packages include System in Package (SiP), Wafer Level Package (WLP), and Package on Package (POP).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a first example embodiment of a system formed by hybrid bonding of two semiconductor packages, in accordance with some embodiments. In this embodiment, the bottom package includes a window which extends entirely from one side of the package and contacts the dummy bond pad.

FIG. 2 is a second example embodiment of a system formed by hybrid bonding of two semiconductor packages, in accordance with some embodiments. In this embodiment, the window in the bottom package is aligned with the dummy bond pad, but does not contact the dummy bond pad.

FIG. 3A is a flow chart illustrating a first method for forming a semiconductor package containing such a window, in accordance with some embodiments. The window both aids in reducing warpage of the package and aids the detection of hybrid bond voids. Various steps of this method are shown in FIGS. 5-16.

FIG. 3B is a flow chart illustrating a second method for forming a semiconductor package containing such a window, which is a variation of the first method described in FIG. 3A. Some alternative steps of this method are shown in FIGS. 17-19.

FIG. 4 is a flow chart illustrating a method for forming a system by joining at least two semiconductor packages using hybrid bonding, in accordance with some embodiments. At least one of the semiconductor packages includes a window for reducing warpage of the package and improving detection of hybrid bond voids. Various steps of this method are shown in FIGS. 20-26.

FIG. 5 is a side cross-sectional view of a processing step.

FIG. 6 is a side cross-sectional view of a processing step.

FIG. 7 is a side cross-sectional view of a processing step.

FIG. 8 is a side cross-sectional view of a processing step.

FIG. 9 is a side cross-sectional view of a processing step.

FIG. 10 is a side cross-sectional view of a processing step.

FIG. 11 is a side cross-sectional view of a processing step.

FIG. 12 is a side cross-sectional view of a processing step.

FIG. 13 is a side cross-sectional view of a processing step.

FIG. 14 is a side cross-sectional view of a processing step.

FIG. 15 is a side cross-sectional view of a processing step.

FIG. 16 is a side cross-sectional view of a processing step.

FIG. 17 is a side cross-sectional view of a processing step for an alternative method, in accordance with some embodiments.

FIG. 18 is a side cross-sectional view of a processing step for the alternative method.

FIG. 19 is a side cross-sectional view of a processing step for the alternative method.

FIG. 20 is a side cross-sectional view of a processing step.

FIG. 21 is a side cross-sectional view of a processing step.

FIG. 22 is a side cross-sectional view of a processing step.

FIG. 23 is a side cross-sectional view of a processing step.

FIG. 24 is a side cross-sectional view of a processing step.

FIG. 25 is a side cross-sectional view of a processing step.

FIG. 26 is a side cross-sectional view of a processing step.

FIG. 27 is an illustration of different plan-view shapes that may be used for the window.

FIG. 28A is an illustration of a first variation of a system which contains multiple “top” packages in combination with a single “bottom” package, in accordance with some embodiments.

FIG. 28B is an illustration of a second variation of a system which contains a “top” package and a “bottom” package, in accordance with some embodiments.

FIG. 29 is a side cross-sectional view illustrating a first variation in which three semiconductor packages are stacked upon each other, and how windows can be formed for inspection of the two different hybrid bond layers formed between the three packages.

FIG. 30 is a side cross-sectional view illustrating a first variation in which three semiconductor packages are stacked upon each other, and how windows can be formed for inspection of the two different hybrid bond layers formed between the three packages.

FIG. 31 is a flow chart illustrating a method for detecting voids in a hybrid bond formed between two semiconductor packages using a window as described herein, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “top”, “bottom”, “front”, “back”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them.

The term “semiconductor package”, as used in the present disclosure, refers to the combination of one or more integrated circuits (also referred to as a die, chip, or microchip) and an interconnect layer that permits the integrated circuit(s) to communicate with one or more other packages. Examples of an interconnect layer may include a redistribution layer (RDL) or an interposer having bond pads or C4 bumps or pillars. Thus, a semiconductor package may have an interconnect layer on only one side, or on both sides, as will be seen further herein. It is noted that in the art, the term “package” is used to refer to many different structures and does not have a single fixed definition.

The present disclosure relates to various methods and structures which are useful in reducing warpage in a semiconductor package and for improving detection of voids in hybrid bond layers. This is done by including a “window” or “aquarium window” structure in the semiconductor package.

In this regard, hybrid bonding refers to the use of both a dielectric bond and a metal bond to form an interconnection between two dies. Each die includes a dielectric layer which contains a plurality of metal bond pads. The dielectric layer on each die is activated (usually by plasma) to be hydrophilic. When the metal bond pads of the two dies are aligned and the dielectric layers of the two dies are brought together, the dielectric layers bond together, referred to herein as a hybrid bond layer. The two-die system is then annealed to cause the metal bond pads to bond together and expand and fill any gaps.

Ideally, after the hybrid bonding is completed, there should be no voids in the bonded area. Voids can cause failure of the whole package. Scanning acoustic microscopy (SAM) can be used to evaluate void quantity, size, and location by detecting changes due to different materials (such as air in the voids). However, high-frequency acoustic waves (GHz range, also known as HF-SAM) are attenuated by metal due to absorption and/or reflection. Because there can be many metal-containing layers between the exterior of the package and the hybrid bond layer, inspection for voids can be difficult.

Warpage of the die due to mechanical stress can also cause failure of the package. Mechanical stresses may arise due to, for example, the differences in the coefficient of expansion between electrically conducting layers and electrically insulating layers or due to the heterogeneous distribution of metal on the die, which can result in uneven or unequal expansion or contraction. Warpage can be measured using known metrology equipment and methods, such as 3-axis strain gauge measurement. The degree of warpage is usually measured in length (micrometers), where zero indicates no warpage (i.e. flat) and a higher value is undesirable. The warpage is generally measured as the difference from the center of the substrate, which is defined as zero. It is noted that the amount of acceptable warpage generally remains the same regardless of the die size (i.e. length and width).

In the present disclosure, at least one “window” or “aquarium window” structure or “warpage control structure” is included in the semiconductor package. The window is formed from an opening or cavity in the package, which is filled with a low-density material. A dummy metal bond pad is aligned with/under the window. The window relieves stresses that contribute to warpage, improving reliability. The window provides an extended path that does not contain metal, and the low-density material of the window also minimizes absorption and/or reflection of high-frequency acoustic waves. These features improve the detection of voids in the hybrid bond layer when using HF-SAM.

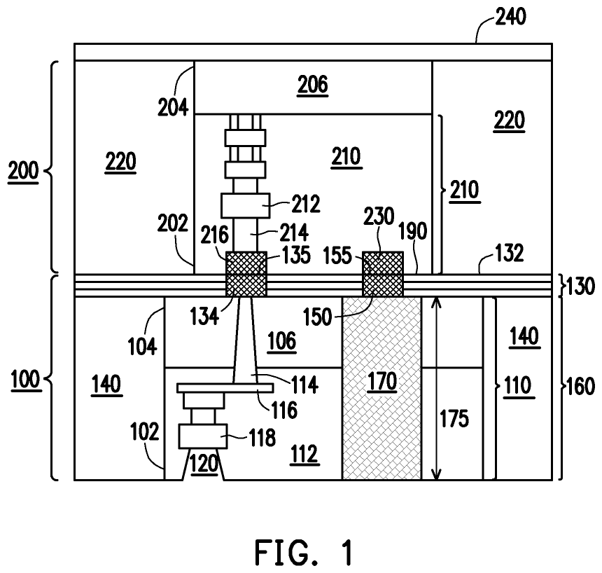

FIG. 1 is a side cross-sectional view showing a first example of a system formed by hybrid bonding of two semiconductor packages, in accordance with some embodiments of the present disclosure, and illustrating some features.

The system includes two semiconductor packages, a first semiconductor package 100 (or bottom package) and a second semiconductor package 200 (or top package).

The first package 100 has a first side 102 and an opposite spaced-apart second side 104, which define the thickness of the package. The first package also includes a die 106. The die itself typically includes a substrate and multiple layers upon the substrate which form an integrated circuit (not shown).

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), tantalum oxide (Ta₂O₅), zirconium dioxide (ZrO₂), or hafnium dioxide (HfO₂); nitrides such as silicon nitride (SiN) or silicon oxynitride (SiON); silicates like hafnium silicate (HfSiO₄) or zirconium silicate (ZrSiO₄); polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

The first package is illustrated as having two interconnect layers 110, 130. The interconnect layer 110 on the first side 102 of the package includes a dielectric material 112 and electrically conductive components within the dielectric material. The interconnect layer 110 may be formed from several different steps that form several smaller layers that together form the interconnect layer, and may also be considered a redistribution layer (RDL). As illustrated here, the electrically conductive components include a through-silicon via (TSV) 114, electrical interconnects 116, and an aluminum pad 118 which is proximate a bump opening 120 that will lead to a C4 bump or pillar. However, generally speaking, any electrical circuit with any desired structure and made up of any desired components is contemplated.

The interconnect layer 130 on the second side 104 of the package is illustrated as a plurality of dielectric or bond film layers 132, which may be formed from oxides, oxynitrides, etc., as desired. A metal bond pad 134 at the surface of the second side is electrically connected to the through-silicon via 114 which passes through the die 106. The bond pad may be made from any suitable electrically conductive material, such as copper, gold, aluminum, iron, and alloys thereof. Thus, the two interconnect layers 110, 130 are also electrically connected to each other.

Gap fill material 140 is present around the first package 102, and is illustrated here on either side of the die. In certain embodiments, the gap fill material 140 is dielectric, and can be an organic dielectric material such as epoxy resin, or an inorganic dielectric material.

A dummy bond pad 150 is located on the second side 104 of the first package, where the hybrid bond layer will be formed. The dummy bond pad can be made of the same material as the metal bond pad, but is not electrically connected to any circuit.

In certain embodiments, the package 100 contains at least one metal-containing layer 160 between the first side 102 and the second side 104 of the package. For example, the interconnect layer 110 may be considered a metal-containing layer. The die also contains one or more metal-containing layers (not shown here).

A warpage control structure or “aquarium” window 170 is present in the first package, and extends from the first side 102 of the package through the thickness of the first package. The window has a depth 175 which may vary to reduce the warpage of the package. As illustrated here in this embodiment, the window extends entirely through the package, including through the die 106, and contacts the dummy bond pad 150. The window 170 does not cut through any electrical circuits of the package.

In certain embodiments, the window is made from a low-density material. Such low-density material may be a material that can be inserted or deposited into an opening, and may be a solid material. If needed, an additional processing step, such as curing or annealing, may be performed to harden the low-density material. In particular embodiments, the low-density material does not contain any metal material, which aids in creating a channel for acoustic waves to travel through with lower attenuation. In such embodiments, the low-density material may be an electrically insulating material (i.e. not electrically conductive).

In particular embodiments, the low-density material has a density which is less than the density of silicon (2.3 g/cc). In some embodiments, the density of the low-density material is from about 0.8 g/cc to 2.3 g/cc. In other embodiments, the density of the low-density material is from about 0.8 g/cc to about 1 g/cc.

In particular embodiments, the low-density material is a polymeric material. In specific embodiments, the low-density material comprises poly(4-methyl-1-pentene) (d˜0.830 g/cc), atactic polypropylene (d˜0.866 g/cc), or a styrene-isoprene block copolymer (d˜0.92 g/cc).

As illustrated here in FIG. 1, the window is formed homogeneously from a single low-density material. However, it is contemplated that the window could be formed heterogeneously if desired. For example, the window could be filled with different layers of different low-density materials, with each layer having a desired depth as needed to change the warpage of the package as desired, or to offer other performance or functionality.

As one example, the warpage control structure might have two different layers, and the depth 175 might have a value D_{T}. The first layer would be formed from a first low-density material of density d1 and have non-zero depth D1. The second layer would be formed from a second low-density material of density d2 and have non-zero depth D2. The densities would be different (i.e. d1≠d2), and D_{T}=D1+D2.

As another example, the warpage control structure might be formed from three different layers L1, L2, and L3, with layer L2 always being between layers L1 and L3. Layer L1 would be formed from a low-density material of density d1 and have non-zero depth D1. Similarly, layer L2 would be formed from a low-density material of density d2 and have non-zero depth D2. Layer L3 would be formed from a low-density material of density d3 and have non-zero depth D3. Again, D_{T}=D1+D2+D3. The density of layer L2 would be different from the densities of layers L1 and L3 (i.e. d2≠d1, and d2≠d3). However, the densities D1 and D3 could be equal or different from each other.

The second package 200 also has a first side 202 and an opposite spaced-apart second side 204. The second package also includes a die 206. As illustrated, the second package only has one interconnect layer 210 on the first side of the package. Again, the die itself typically includes a substrate and multiple layers which form an integrated circuit.

Continuing, the interconnect layer 210 on the first side 202 of the second package can also be considered a redistribution layer (RDL). As illustrated here, the electrically conductive components include electrical interconnects 212, a bond pad via 214, and a metal bond pad 216 at the surface of the first side 202. A dummy bond pad 230 is also located on the first side 202 of the second package. Gap fill material 220 is also present. The second side 204 of the second package is covered with an electrically insulating layer 240.

A hybrid bond layer 190 is present between the first package 100 and the second package 200. The metal bond pad 134 of the first package is bonded to the metal bond pad 216 of the second package, with this hybrid bond being indicated with reference numeral 135. The dummy bond pad 150 of the first package is bonded to the dummy bond pad 230 of the second package, with this hybrid bond being indicated with reference numeral 155.

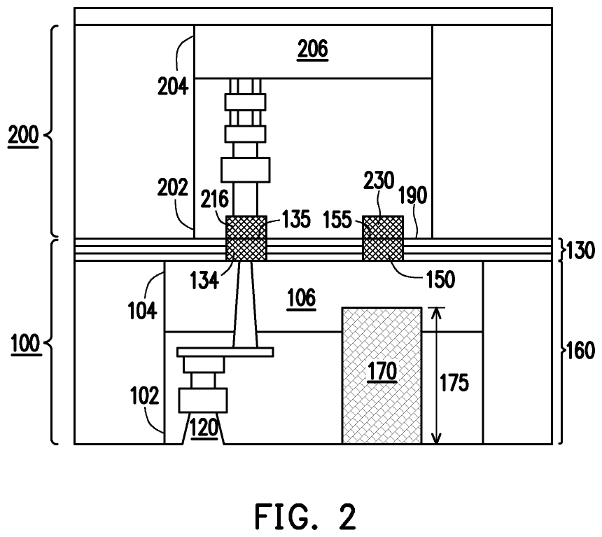

FIG. 2 is a side cross-sectional view showing a second example of a system formed by hybrid bonding of two semiconductor packages. This system is similar to the system illustrated in FIG. 1. However, here the warpage control structure or window 170 has a depth 175 which extends through the at least one metal-containing layer 160. Put another way, the depth 175 of the window is greater than the depth 165 of the metal-containing layer. In this embodiment, the window does not contact the dummy bond pad 150.

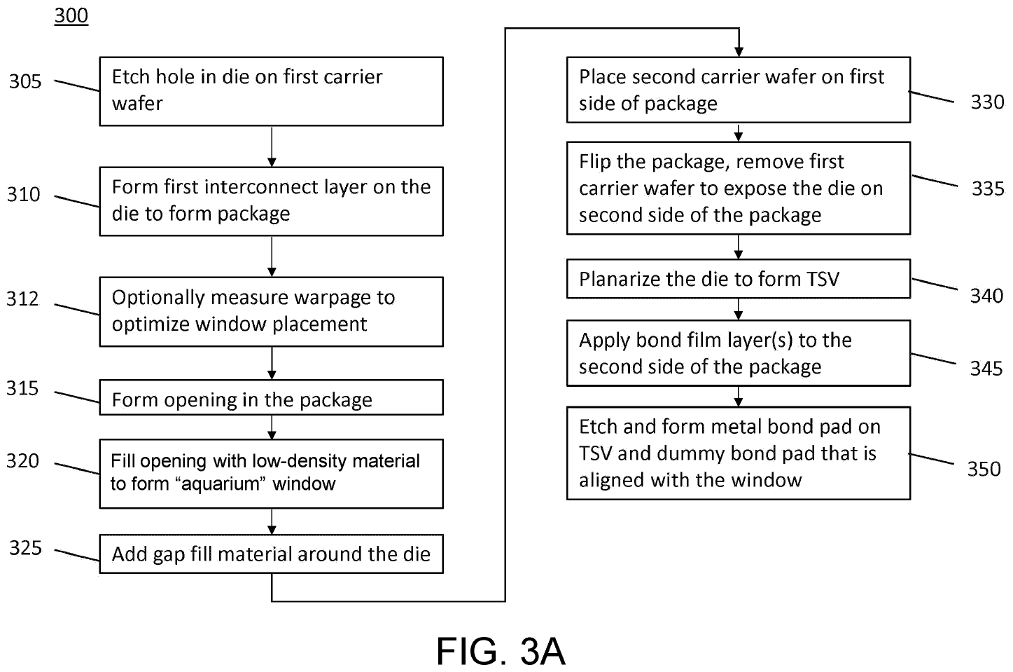

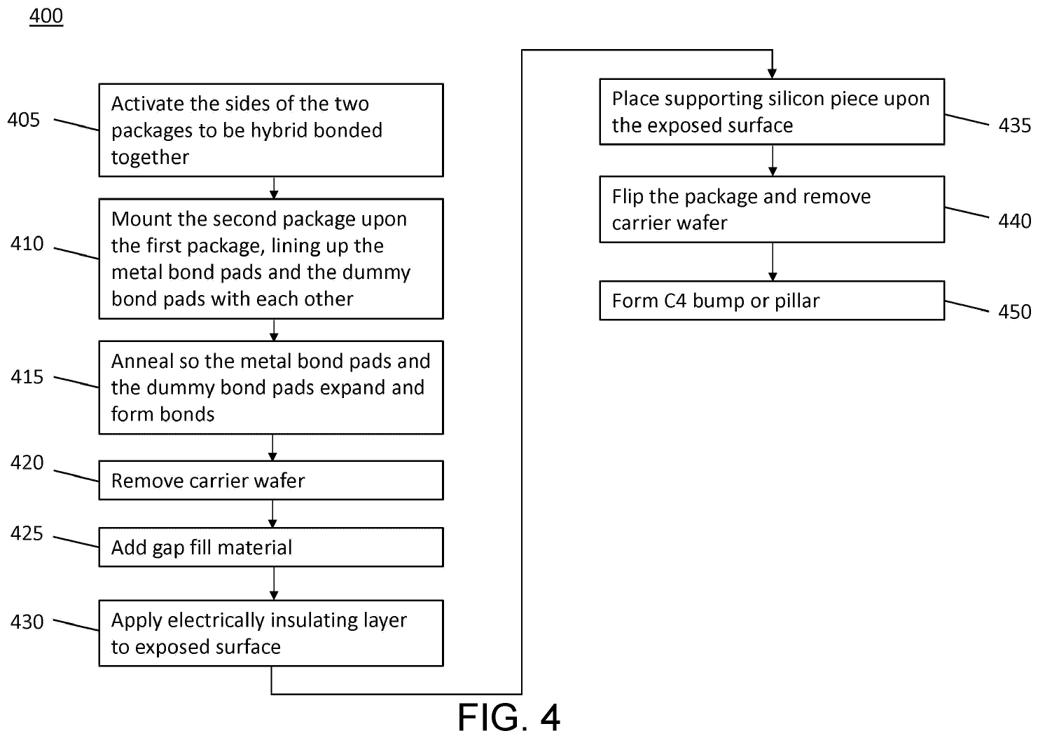

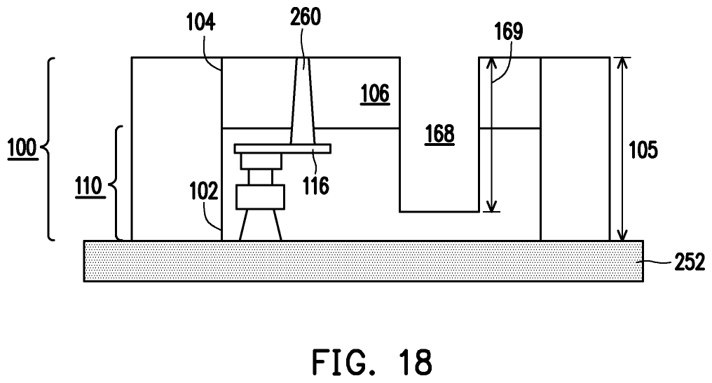

FIG. 3A and FIG. 3B are flow charts illustrating some methods 300 of the present disclosure, in accordance with some embodiments. These methods aid in making a semiconductor package with reduced warpage by including a warpage control structure or an “aquarium” window within the package. FIGS. 5-16 illustrate various steps of the method of FIG. 3A, and these figures are discussed together. FIGS. 17-19 also illustrate some steps for the alternative method of FIG. 3B. It is noted that these methods also describe the formation of a through-silicon via (TSV) through a die in conjunction with the window. However, the processing steps for forming such a TSV may be performed completely separately from the steps for forming the “aquarium” window.

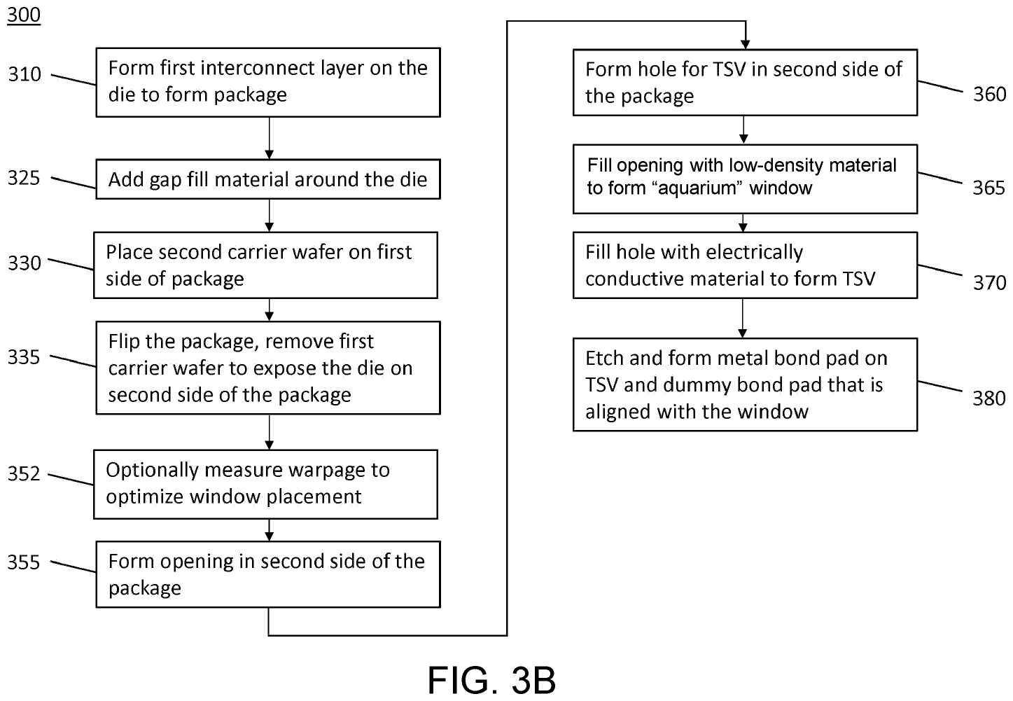

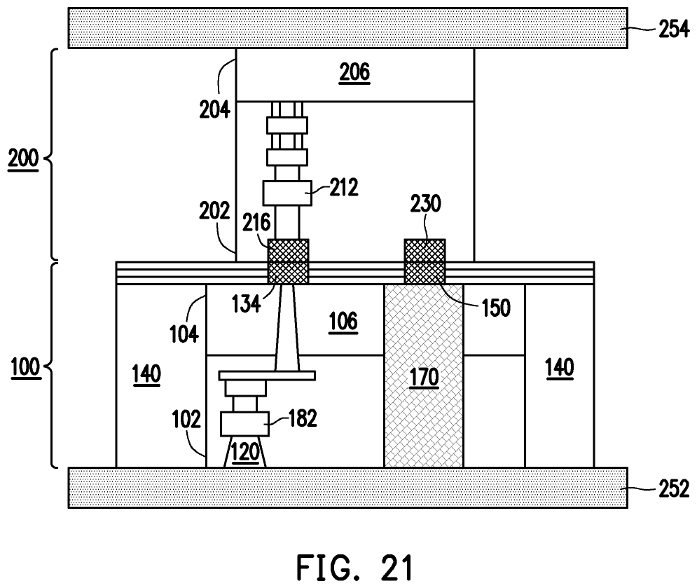

FIG. 4 is a flow chart illustrating some additional methods 400 of the present disclosure, in accordance with some embodiments. These methods form a system by joining at least two semiconductor packages using hybrid bonding, in accordance with some embodiments. FIGS. 20-26 illustrate various steps of the method, and these figures follow after the discussion of FIGS. 5-19.

Referring first to FIG. 5, this figure illustrates one example of the beginning state of the die 106 prior to making the package. The die 106 is mounted to a first carrier wafer 250. The die includes a substrate and multiple layers which form an integrated circuit.

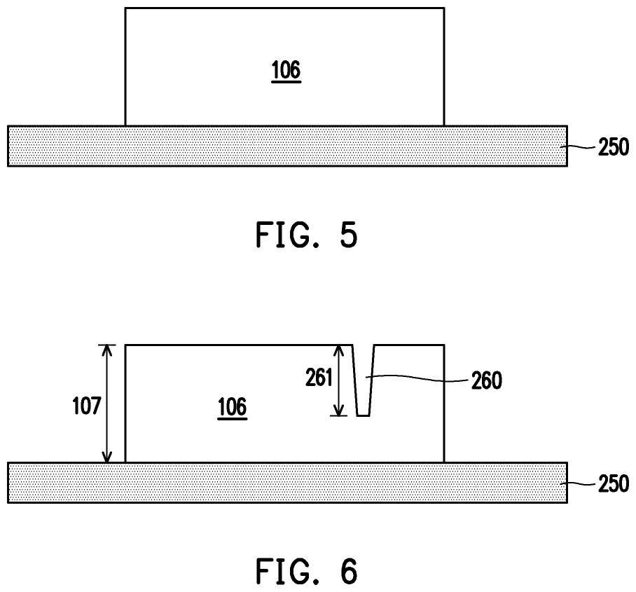

Next, in FIG. 6 and step 305 of FIG. 3A, a hole 260 is etched into the die 106. The height 261 of the hole 260 is less than the thickness 107 of the die. In some embodiments, a photolithographic patterning processes uses ultraviolet light to transfer a desired mask pattern to a photoresist layer. Etching is then used to transfer to the pattern to a layer below the photoresist layer.

Generally, any etching step used herein may be performed using wet etching, dry etching, or plasma etching processes such as reactive ion etching (RIE) or inductively coupled plasma (ICP), high density plasma (HDP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

FIG. 6 shows the result after one such round of patterning, developing, and etching, which forms the hole 260.

These process steps can be repeated multiple times with different patterns to build different layers. Next, in step 310 of FIG. 3A, a first interconnect layer is formed.

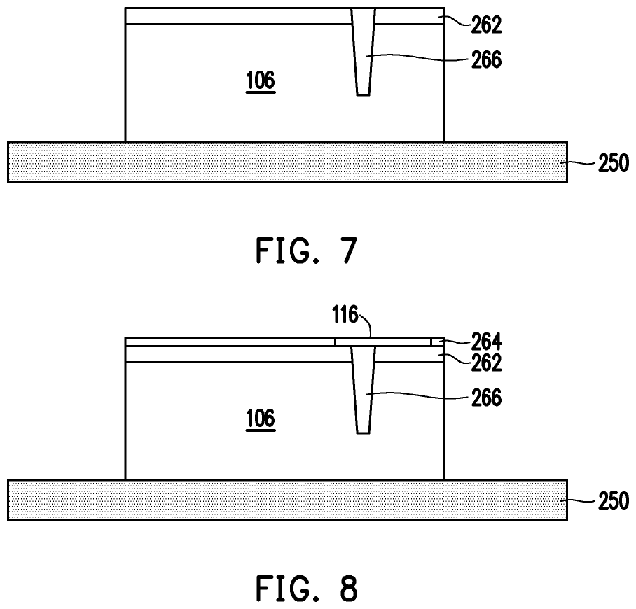

FIG. 7 illustrates the result after additional rounds of patterning, developing, and etching. A first dielectric layer 262 has been formed on either side of the hole 260. In addition, a metal has been deposited into the hole to form a via 266. Such deposition may be performed by physical vapor deposition (PVD), chemical vapor deposition (CVD), atomic layer deposition (ALD), or other suitable technique.

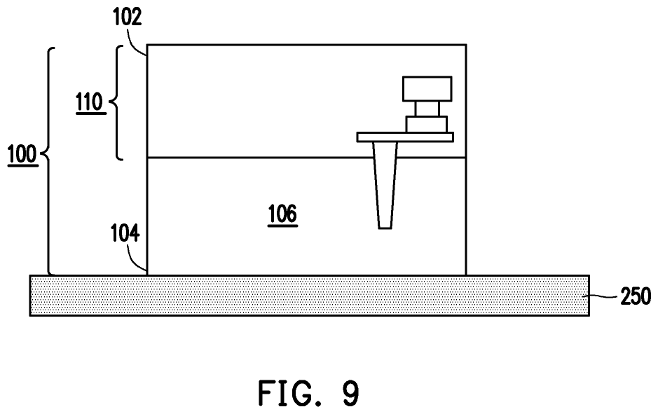

FIG. 8 illustrates the result after further rounds of patterning, developing, etching, and deposition. A second dielectric layer 264 has been formed, and an electrical interconnect 116 has been formed in the second dielectric layer.

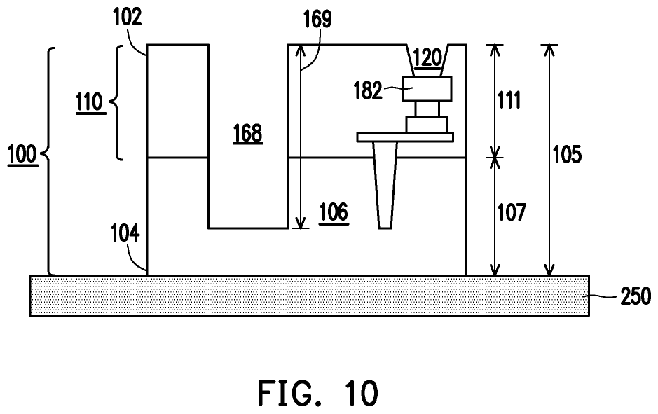

Additional rounds of patterning, developing, etching, and deposition are performed as desired. FIG. 9 illustrates the first interconnect layer 110. The individual layers formed each round can be considered to form the overall interconnect layer 110, which can also be considered a redistribution layer (RDL). The first interconnect layer 110 as well as the various layers present in the die 106 contain metal, and may each be considered a metal-containing layer.

The combination of the die 106 and the first interconnect layer 110 is referred to as a semiconductor package 100. The package 100 has a first side 102 and a second side 104.

Next, in optional step 312 of FIG. 3A, the warpage of the package 100 is measured. As discussed above, this can be done using known methods. A desired “aquarium” window depth and location that optimizes the reduction in warpage of the package can then be determined. For example, the window could be located in a high-stress location, such that the stress is relieved. Alternatively, the warpage of the die could have been previously measured, and can be used to determine the desired window depth.

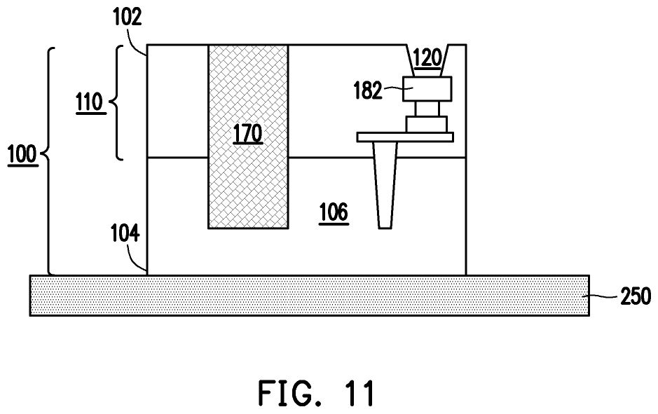

Next, in FIG. 10 and in step 315 of FIG. 3A, an opening 168 is formed in the first side 102 of the package. As illustrated here, the first interconnect layer 110 has a depth 111, and the die 106 has a depth 107, and the package has a depth 105 which is the sum of those two depths. The depth 169 of the opening is less than the package depth 105. This opening will eventually form the “aquarium” window of the present disclosure. The depth may correspond to the desired depth determined in optional step 312 for reducing the overall warpage. Also shown here is a separate bump opening 120 which connects to the electrical components 182. The opening 168 may be formed via etching, or could also be made by laser drilling.

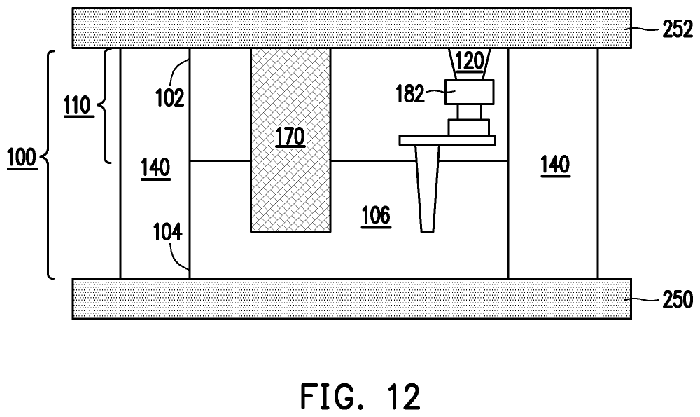

Then as shown in FIG. 11 and in step 320 of FIG. 3A, the opening is filled with a low-density material to form the “aquarium” window 170.

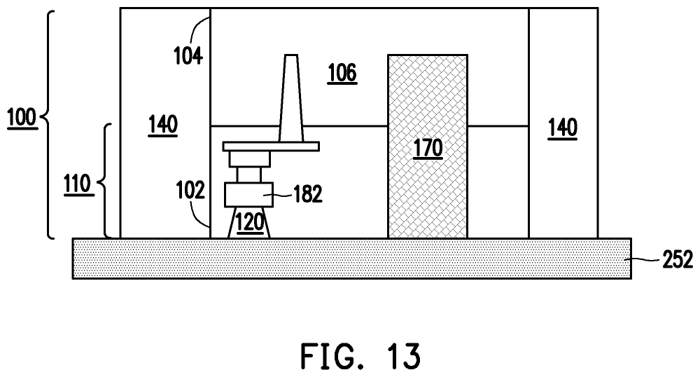

Next, in step 325 of FIG. 3A and referring to FIG. 12, gap fill material 140 is added around the die 106 and the interconnect layer 110. In step 330, a second carrier wafer 252 is then placed upon the first side 102 of the package. FIG. 12 shows the resulting structure.

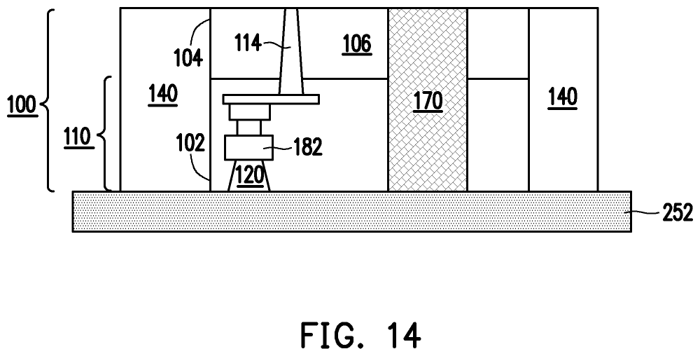

Then, in step 335 of FIG. 3A and referring to FIG. 13, the package is flipped and the first carrier wafer 250 is removed. FIG. 13 shows the resulting structure. The second side 104 of the package, which includes the die 106, is now exposed.

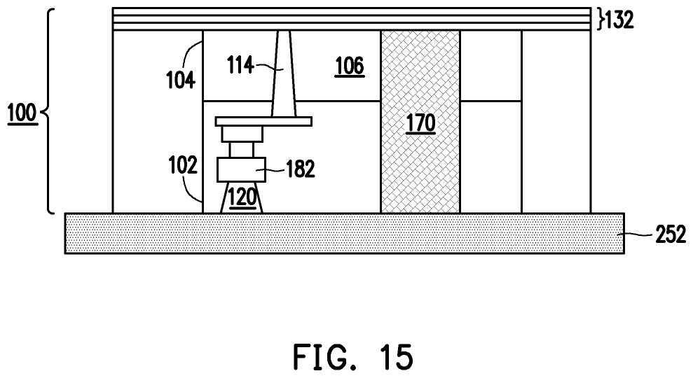

Then, in step 340 of FIG. 3A and referring to FIG. 14, the die is planarized to reduce the thickness of the die (i.e. thinning of the die or its substrate) and convert the via into a through-silicon via (TSV) 114. The planarizing may be performed, for example, using a chemical mechanical polishing (CMP) process. FIG. 14 shows the resulting structure after this step.

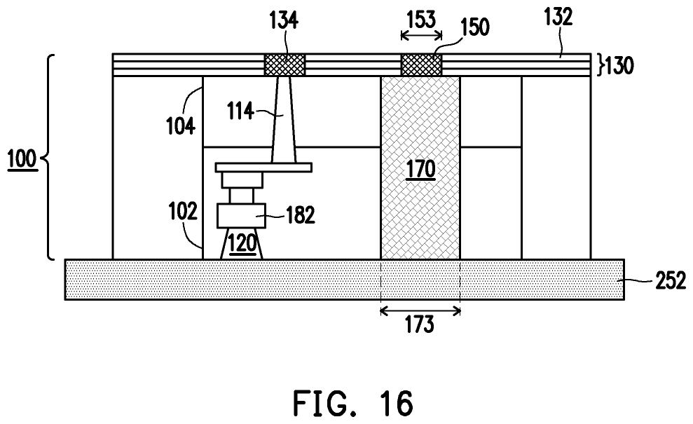

Then, in step 345 of FIG. 3A and referring to FIG. 15, one or more bond film layers 132 are applied to the second side 104 of the semiconductor package. The exposed bond film layer is suitable for forming oxide/oxide bonds, although other suitable bond materials and interfaces can also be used.

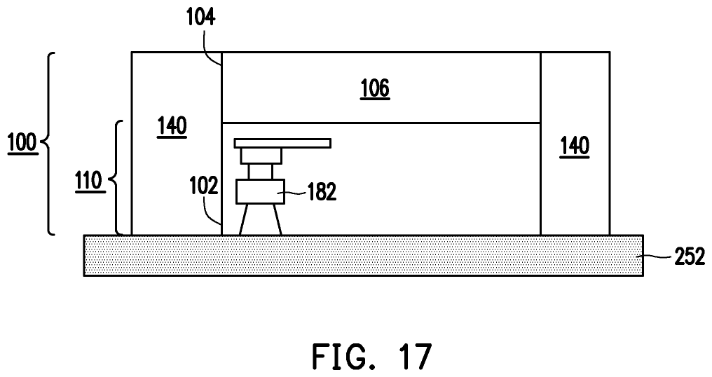

Next, in step 350 of FIG. 3A and referring to FIG. 16, the bond film layer(s) 132 are etched and a metal bond pad 134 is formed upon the TSV 114. A dummy bond pad 150 is also formed that is aligned with the window 170. The combination of the bond film layer(s) 132 and the metal bond pad 134 can be considered a second interconnect layer 130.

As shown here, the dummy bond pad contacts the window. In embodiments, where the window is not exposed upon the second side 104 of the package, the dummy bond pad is formed above the window. As indicated here, the window has a width 173, and the dummy bond pad has a width 153. In particular embodiments, the width 153 of the dummy bond pad is from about one (1) micrometer (μm) to about five (5) micrometers. In other particular embodiments, the width 173 of the window is from about 1.5 times to about three (3) times the width 153 of the dummy bond pad. Put another way, the ratio of the window width 173 to the dummy bond pad width 153 is from about 1.5:1 to about 3:1. The resulting semiconductor package 100 of FIG. 16 thus has reduced warpage compared to a package that does not contain such a window 170.

FIG. 3A and FIGS. 5-16 illustrate a method 300 in which the “aquarium” window is formed from the surface on the first side of the package. In these figures, the TSV 114 can be considered as being formed through a via-first or via-middle process, where the die or substrate. FIG. 3B and FIGS. 17-19 illustrate an alternative method 300 in which the “aquarium” window is formed from the surface on the second side of the package, along with a via-last process for forming the TSV.

In the alternative method, the first interconnect layer is formed as described in step 310. After the gap fill material is applied, the second carrier wafer 252 is applied, the package is flipped, and the first carrier wafer is removed 250 as described in steps 325, 330, and 335, the resulting structure is illustrated in FIG. 17. Here, the second side 104 of the package and the die 106 are exposed. In optional step 352 of FIG. 3B, the warpage may be measured to determine optimal window characteristics.

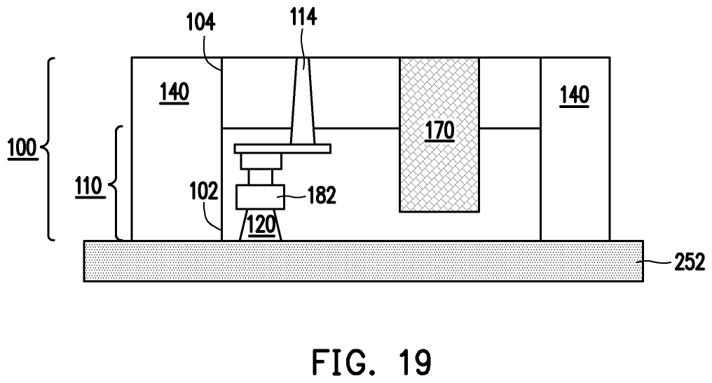

Next in step 355 of FIG. 3B and as illustrated in FIG. 18, an opening 168 is formed in the second side 104 of the package. As illustrated here, the opening has a depth 169 which is less than the package depth 105. In step 360, a hole 260 is also formed which is aligned with the electrical interconnect 116, similar to step 305 of FIG. 3A. In this regard, the electrical interconnect can also act as an etch stop layer for controlling the depth of the hole 260. The resulting structure is shown in FIG. 18.

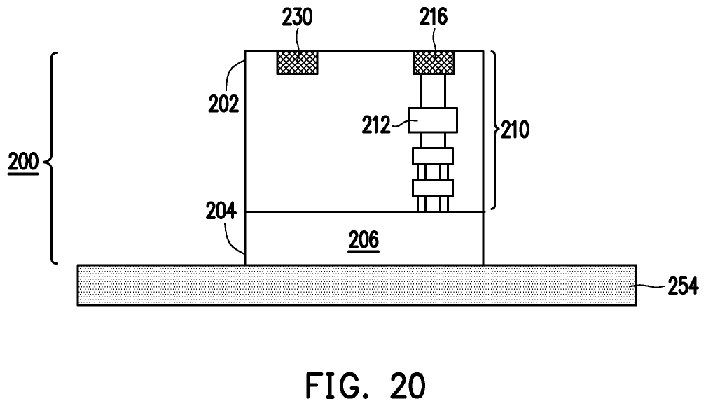

Next, in step 365 of FIG. 3B, the opening 168 is then filled with a low-density material to form the warpage control structure or “aquarium” window 170. In step 370, the hole is also filled with electrically conductive material to form the TSV 114. The resulting structure is shown in FIG. 19, and corresponds essentially to that of FIG. 14. In step 375, the bond film layer(s) 132 are formed. In step 380, the bond film layer(s) are etched, and a metal bond pad 134 is formed upon the TSV 114. A dummy bond pad 150 is also formed which is aligned with the window 170. These two steps correspond to steps 345, 350 of the method of FIG. 3A. The resulting structure is seen in FIG. 16.

It is noted that although the window 170 of FIG. 19 is not on the surface of the first side 102, it still reduces attenuation of any acoustic waves passing through it. As a result, the warpage control structure or window 170 can generally be located so as to reduce warpage of the package, can be placed in a desired location within the thickness of the package, and can be made with a desired thickness.

Referring now to FIG. 4, an example method for forming a system by joining at least two semiconductor packages using hybrid bonding according to some embodiments of the present disclosure is described.

The methods described in FIG. 4 begin with a first semiconductor package 100 (or bottom package) and a second semiconductor package 200 (or top package). The first semiconductor package 100 is shown in FIG. 16, and the second semiconductor package 200 is shown in FIG. 20.

The second package 200 of FIG. 20 is similar in structure to the first package. The second package includes a second die 206 shown here contacting a third carrier wafer 254. The interconnect layer 210 is located on the first side 202 of the package, and electrical interconnects 212 are shown. The metal bond pad 216 and dummy bond pad 230 are illustrated as being present on the first side 202 of the second package. The die 206 is present on the second side 204 of the second package.

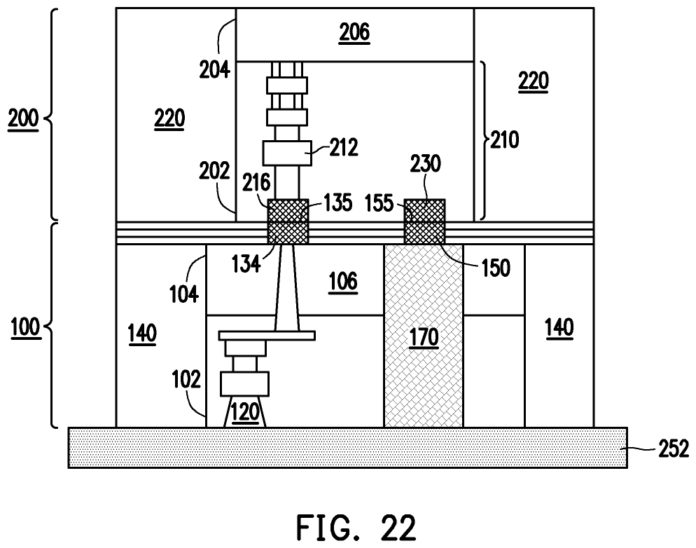

Referring to FIG. 21, when mounted, the first side 202 of the second package 200 will contact the second side 104 of the first package 100. In step 405, the appropriate sides/surfaces of the two packages are activated by plasma, so that they are hydrophilic.

Next, in step 410, the second package 200 is mounted upon the first package 100 so that the metal bond pads 134, 216 and the dummy bond pads 150, 230 of the two packages line up with each other. When brought together, the two surfaces will undergo spontaneous oxide-oxide bonding and form a system.

Next, in step 415 of FIG. 4, the system is annealed so that the metal bond pads 134, 216 and the dummy bond pads 150, 230 will expand and form bonds 135, 155 between them.

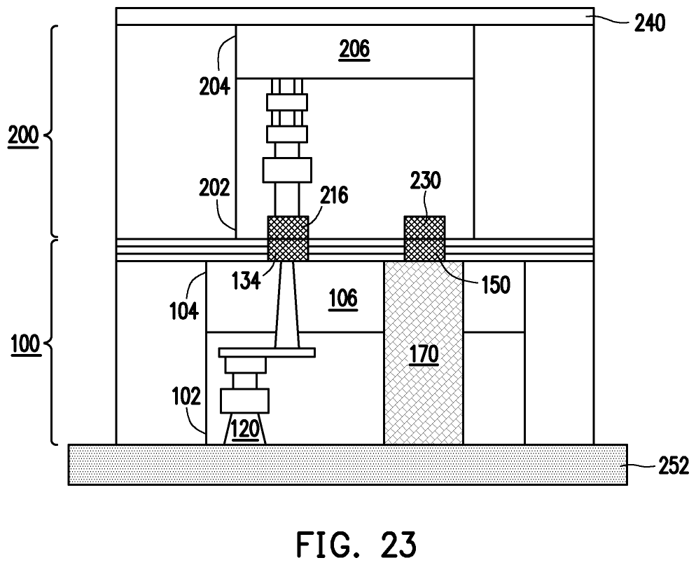

In step 420 of FIG. 4, the third wafer carrier 254 is then removed. In step 425, gap fill material 220 is added around the die 206 and the interconnect layer 210 of the second package. The resulting structure is shown in FIG. 22.

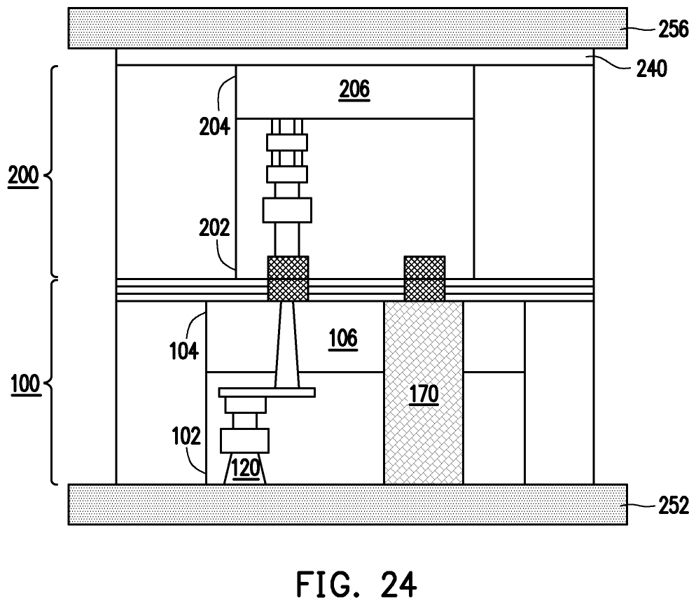

Then, in step 430 of FIG. 4, an electrically insulating layer 240 is applied to the exposed surface of the second package 200. The resulting structure is shown in FIG. 23.

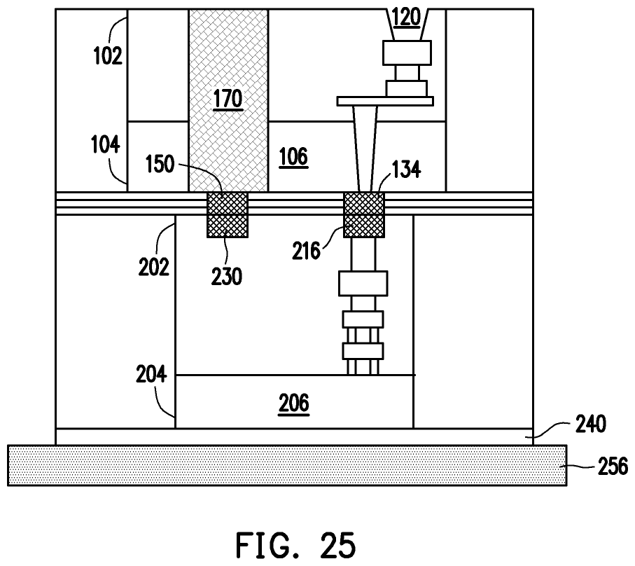

In step 435, a fourth carrier wafer 256 or supporting silicon piece is then placed upon the exposed side of the system, i.e. second side 204 of the second package. FIG. 24 shows the resulting structure.

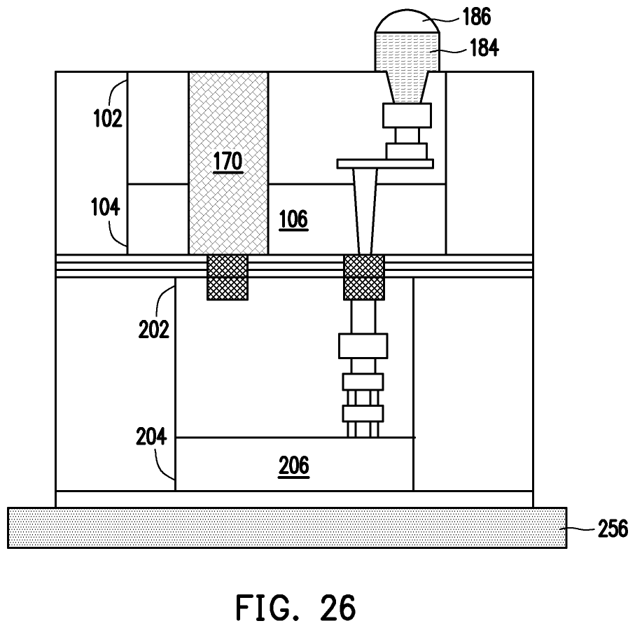

Then, in step 440 of FIG. 4 and referring to FIG. 25, the package is flipped and the third carrier wafer 254 is removed. FIG. 25 shows the resulting structure. The first side 102 of the first package, which includes the bump opening 120, is now exposed.

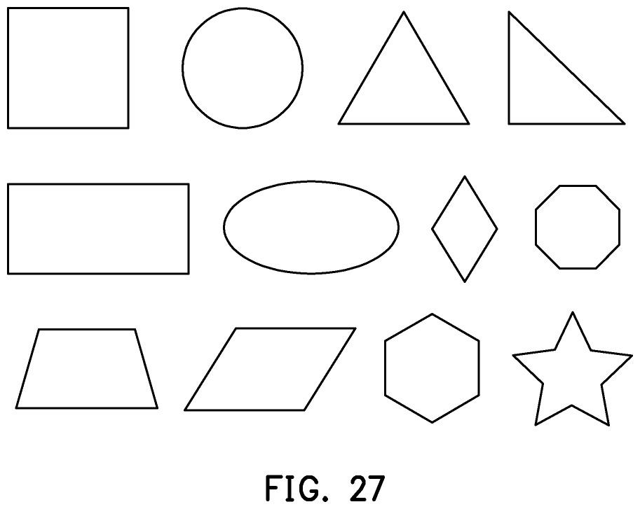

Next, in step 445 of FIG. 4 and referring to FIG. 26, a C4 bump or pillar is formed. As illustrated here, a pillar 184 is made of copper, and fills the bump opening 120 and forms an electrical connection. A solder ball or bump 186 is present upon the pillar 184. These structures can be formed by appropriate masking and deposition steps. The resulting system may itself be referred to as a single package.

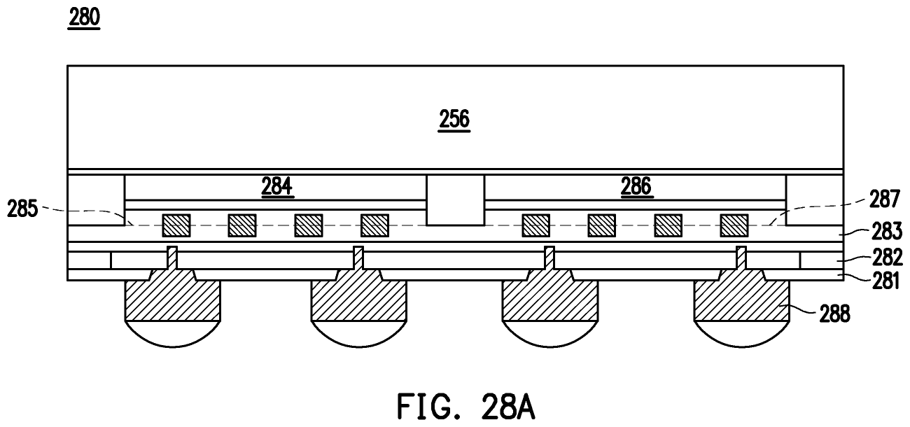

FIG. 27 shows various shapes that the warpage control structure or window 170 may have when seen from a plan view (perpendicular to the side cross-sectional views of FIGS. 5-26). The window may have any shape which can be implemented. Some particular shapes illustrated in this figure include one-sided circular and elliptical shapes. Polygonal shapes illustrated here include square, equilateral triangle, right triangle, isosceles triangle, rectangle, diamond, octagon, trapezoid, rhombus, hexagon, and five-point star shapes.

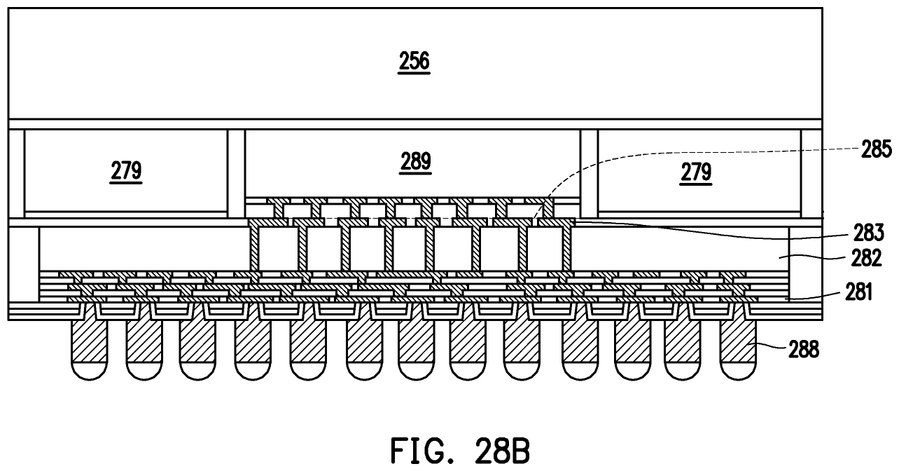

FIG. 28A is a side cross-sectional view of a first embodiment of a System on Integrated Chip (SoIC) that illustrates additional variations which are possible with the methods and devices of the present disclosure. SoIC offers heterogeneous integration of known good dies (KGDs) with different chip sizes, functionalities and wafer node technologies. The resulting system has a smaller footprint, a thinner profile, increased performance, lower power, and minimized RLC (resistance-inductance-capacitance). The system can integrate active and passive chips into a new system which is electrically identical to native System-on-Chip to achieve better form factor and performance. Generally speaking, any number of packages can be bonded to any given package.

The system 280 includes a bottom package 282 having two interconnect layers 281, 283, one on each side of the bottom die 282. The bottom package 282 is connected to two smaller top packages 284, 286, each top package having its own die. The bottom package is hybrid bonded to the two top packages through two hybrid bond layers 285, 287. The two top packages 284, 286 are themselves bonded to a supporting silicon piece 256. In this system, the bottom package could include two separate windows 170 (not labeled here) for inspecting the hybrid bond layers, or each top package could include a window for inspecting the hybrid bond layers. Such inspection could occur either before the supporting silicon piece 256 is mated and/or the C4 bumps 288 are formed, as appropriate.

FIG. 28B is a side cross-sectional view of a second embodiment of a System on Integrated Chip (SoIC) The system 280 includes a bottom package 282 having two interconnect layers 281, 283, one on each side of the bottom die 282. In some embodiments, the bottom package is a central processing unit (CPU). The bottom package 282 is connected to a smaller top package 289. In some embodiments, the top package is a memory chip, such as static random access memory (SRAM). The bottom package is hybrid bonded to the top package through hybrid bond layer 285.

As illustrated here, the top package is smaller than the bottom package. Thus, two non-functional or “dummy” chips 279 are also bonded to the bottom package. The two dummy chips 279 and the top package 289 are also bonded to a supporting silicon piece 256. The C4 bumps 288 are also visible. In this system, the bottom package could include a window for inspecting the hybrid bond layers, or the top package could include a window for inspecting the hybrid bond layers.

FIGS. 5-28 are side cross-sectional views which illustrate the methods and devices in terms of hybrid bonding of two chips or die. However, the methods described herein are also applicable to wafer-level bonding of two wafers together and inspection of the hybrid bond layer prior to the wafers being diced into two-chip packages.

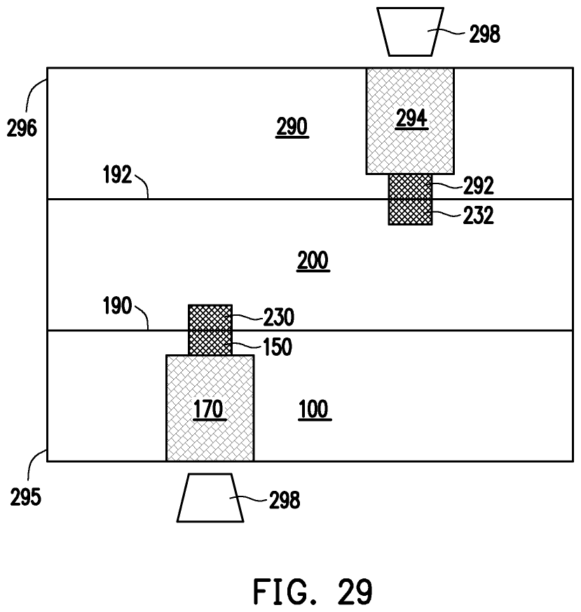

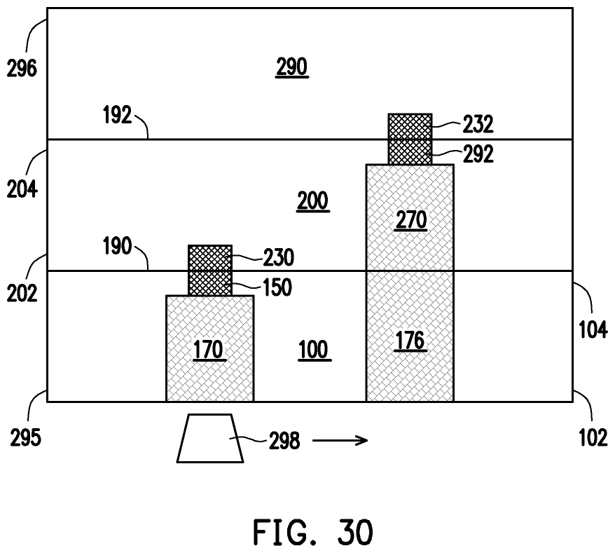

Continuing, while FIGS. 5-28 illustrate only two packages, the methods of the present disclosure are also applicable to chip stacks formed from any number of individual packages. FIG. 29 and FIG. 30 illustrate two examples in which the hybrid bond layers of multi-level stacks can be inspected/qualified using the methods of the present disclosure. In these two examples, only the dummy bond pads and windows are illustrated.

These two figures illustrate a three-layer stack. Referring first to FIG. 29, a first semiconductor package 100 is hybrid bonded to a second semiconductor package 200 on one side to form a first hybrid bond layer 190. A third semiconductor package 290 is hybrid bonded to the other side of the second semiconductor package 200 to form a second hybrid bond layer 192. Along the first hybrid bond layer 192, the second semiconductor package 200 includes dummy bond pad 230. The first semiconductor package 100 includes dummy bond pad 150, which is bonded to dummy bond pad 230. The first package also includes a warpage control structure or window 170 which is aligned with the bonded dummy bond pads 150, 230. Similarly, along the second hybrid bond layer 192, the second semiconductor package 200 includes dummy bond pad 232. The third semiconductor package 290 includes dummy bond pad 292, which is bonded to dummy bond pad 232, and also includes a warpage control structure or window 294 which is aligned with the bonded dummy bond pads 232, 292.

It is contemplated that in the system of FIG. 29, the hybrid bond between the dummy bond pads in the first hybrid bond layer 190 would be inspected by scanning acoustic microscope 298 through window 170 on the first side 295 of the system after the first semiconductor package 100 and the second semiconductor package 200 are bonded together, but before the third semiconductor package 290 is hybrid bonded to the other side of the second semiconductor package 200. After inspection of the first hybrid bond layer 190, a carrier wafer would be bonded to the first semiconductor package 100, the two-package combination would be flipped, and the third semiconductor package 290 would then be hybrid bonded to the second semiconductor package 200. The hybrid bond between the dummy bond pads in the second hybrid bond layer 192 would then be inspected through window 294 on the second side 296 of the system.

Referring now to FIG. 30, a first semiconductor package 100 is hybrid bonded to a second semiconductor package 200 on one side to form a first hybrid bond layer 190. A third semiconductor package 290 is hybrid bonded to the other side of the second semiconductor package 200 to form a second hybrid bond layer 192. Along the first hybrid bond layer 190, the second semiconductor package 200 includes dummy bond pad 230. The first semiconductor package 100 includes dummy bond pad 150 (which is bonded to dummy bond pad 230) and also includes a warpage control structure or window 170 which is aligned with the bonded dummy bond pads 150, 230. Similarly, along the second side 204 or the second hybrid bond layer 192, the second semiconductor package 200 includes dummy bond pad 232. The third semiconductor package 290 includes dummy bond pad 292, which is bonded to dummy bond pad 232.

However, with respect to the second hybrid bond layer, the second semiconductor package 200 also includes a warpage control structure or window 270 which is aligned with the bonded dummy bond pads 232, 292 and extends to the first side 202 of the second package or the first hybrid bond layer 190. The first semiconductor package 100 includes a second separate or “pass-through” window 176 or warpage control structure, which is aligned with the window 270 in the second semiconductor package 200 and the bonded dummy bond pads 232, 292. This “pass-through” window 176 extends entirely through the first package 100, from the first side 102 of the package to the second side 104 or the first hybrid bond layer 190. Depending on the number of packages which are stacked, a plurality of warpage control structures or windows may be present in a given package.

It is contemplated that in the system of FIG. 30, the three packages 100, 200, 290 are first bonded together. Subsequently, the hybrid bond between the dummy bond pads in the first hybrid bond layer 190 would be inspected through window 170. The hybrid bond between the dummy bond pads in the second hybrid bond layer 192 would then be inspected through the combination of window 176 in the first semiconductor package 100 and window 270 in the second semiconductor package 200, which operate together as a single channel for acoustic waves. This would permit verification of both hybrid bond layers from the same side 295 of the system by the scanning acoustic microscope 298. These principles could be extended to permit inspection of any number of hybrid bond layers formed between packages, so long as an appropriate number of windows are present in each package. In this regard, it is noted that the dummy bond pads 232, 292 between the second semiconductor package 200 and the third semiconductor package 290 should not be in-line with the dummy bond pads 150, 230 between the first semiconductor package 100 and the second semiconductor package 200 in this embodiment, because the presence of the first set of dummy bond pads 150, 230 in the first hybrid bond layer within the path created by the windows would cause attenuation and confuse readings for the second hybrid bond layer 232, 292 further downstream from the scanning acoustic microscope 298.

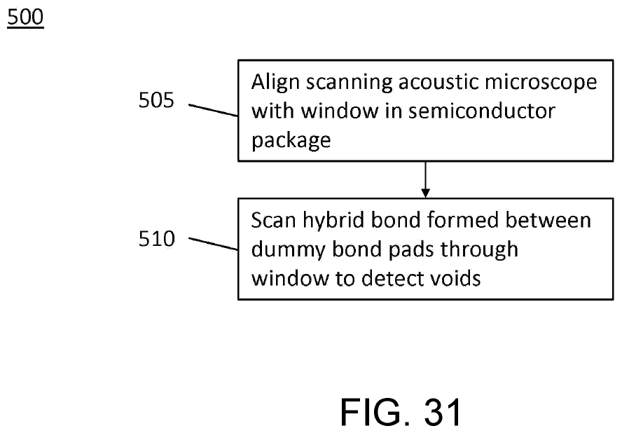

FIG. 31 is a flow chart illustrating a method 500 for detecting voids in a hybrid bond formed between two semiconductor packages using a window as described herein, in accordance with some embodiments. Such inspection usually occurs before C4 bumps are added.

In step 505 of FIG. 31, referring to both FIG. 29 and FIG. 30, a scanning acoustic microscope is aligned with a window 170 in the first semiconductor package 100. The window comprises a low-density material, as previously described. The window is also aligned with a hybrid bond 155 formed between a dummy bond pad 150 of the first semiconductor package and a dummy bond pad 230 of the second semiconductor package.

In step 510 of FIG. 31, the hybrid bond 155 between the dummy bond pads is scanned through the window to determine the presence of voids. The condition of the hybrid bond 155 between the dummy bond pads acts as a proxy for the condition of the hybrid bond 135 (see FIG. 1) between the metal bond pads that are part of an electrical circuit, which cannot be directly scanned as reliably due to attenuation caused by metal between the metal bond pads and the scanning acoustic microscope.

When performed in the system of FIG. 30, to scan the bond between dummy bond pads in the second hybrid bond layer 192, the window 176 of the first semiconductor package extends entirely through the first semiconductor package and is aligned with the window 270 in the second semiconductor package. The scanning acoustic microscope is thus aligned with the window in the second semiconductor package through the window of the first semiconductor package.

The methods and devices of the present disclosure including an “aquarium window” structure have many advantages. The window relieves stresses that contribute to warpage of the die/package, improving reliability. In addition, high-frequency waves do not penetrate metal-containing layers, oxide/nitride layers, or the silicon substrate very well. The window also provides an extended path that does not contain metal, and the low-density material of the window also minimizes absorption and/or reflection of high-frequency acoustic waves. Any metal/oxide/nitride blockages are reduced or minimized to allow acoustic waves to travel to the dummy hybrid bond between the dummy bond pads. This improves the detection of voids in the hybrid bond layer when using HF-SAM. Variable functionality and performance can be obtained through variable depths, densities, and cross-sectional shapes of the windows.

It is noted that in some embodiments, dummy bond pads are not present. In such embodiments, the presence of the window still reduces warpage. However, detection of voids in the hybrid bond layer is not enabled due to the absence of the dummy bond pads.

Some embodiments of the present disclosure thus relate to methods for making a semiconductor package with reduced warpage. A semiconductor package is prepared that comprises a first side, a second side, and at least one metal-containing layer between the first side and the second side. An opening is formed in the semiconductor package that extends through the at least one metal-containing layer. The opening is filled with a low-density material to form a warpage control structure. The warpage control structure relieves stress that causes warpage in the semiconductor package. In some more specific embodiments, a dummy bond pad is formed on the semiconductor package that is aligned with the warpage control structure. The warpage control structure acts as a “window” to the dummy bond pad.

Other embodiments relate to semiconductor packages comprising a first side and a second side. At least one metal-containing layer is present between the first side and the second side. A warpage control structure extends through the at least one metal-containing layer. The warpage control structure comprises a low-density material. In some further embodiments, the second side includes a dummy bond pad, and the warpage control structure is aligned with the dummy bond pad and acts as a window thereto.

Also disclosed in various embodiments are methods for detecting voids in a hybrid bond formed between a first semiconductor package and a second semiconductor package. A scanning acoustic microscope is aligned with a window in the first semiconductor package, wherein the window comprises a low-density material and is aligned with a hybrid bond formed between a dummy bond pad on the first semiconductor package and a dummy bond pad on the second semiconductor package. The hybrid bond formed between the dummy bond pads is scanned through the window to detect voids.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a semiconductor package with reduced warpage, comprising:
providing a semiconductor package comprising a first side, a second side, and at least one metal-containing layer between the first side and the second side;
forming an opening in the semiconductor package that extends through the at least one metal-containing layer; and
filling the opening with a low-density material to form a warpage control structure;
wherein the warpage control structure relieves stress that causes warpage in the semiconductor package.

2. The method of claim 1, further comprising forming a dummy bond pad on the semiconductor package that is aligned with the warpage control structure.

3. The method of claim 2, wherein the warpage control structure extends through the package to contact the dummy bond pad.

4. The method of claim 2, wherein the warpage control structure extends through the package and does not contact the dummy bond pad.

5. The method of claim 1, wherein the low-density material has a density which is less than silicon.

6. The method of claim 1, wherein the low-density material has a density of about 0.8 g/cc to about 1 g/cc.

7. The method of claim 1, wherein the low-density material comprises poly(4-methyl-1-pentene), atactic polypropylene, or a styrene-isoprene block copolymer.

8. The method of claim 1, wherein the semiconductor package further comprises a die, the second side of the semiconductor package is a back side of the die and a dummy bond pad is located on the back side of the die, the at least one metal-containing layer is a redistribution layer on a front side of the die, and the warpage control structure extends from the front side of the die towards the dummy bond pad.

9. A semiconductor package, comprising:
a first side, a second side, and at least one metal-containing layer present between the first side and the second side; and
a first warpage control structure extending through the at least one metal-containing layer, the first warpage control structure comprising a low-density material.

10. The semiconductor package of claim 9, wherein the second side includes a dummy bond pad and the first warpage control structure is aligned with the dummy bond pad.

11. The semiconductor package of claim 10, wherein the first warpage control structure extends from the first side through the at least one metal-containing layer and does not contact the dummy bond pad.

12. The semiconductor package of claim 9, wherein the low-density material has a density of about 0.8 g/cc to about 1 g/cc.

13. The semiconductor package of claim 9, wherein the low-density material comprises poly(4-methyl-1-pentene), atactic polypropylene, or a styrene-isoprene block copolymer.

14. The semiconductor package of claim 9, wherein the first warpage control structure has a polygonal plan view cross-sectional shape.

15. The semiconductor package of claim 9, further comprising a pass-through window that extends entirely through the first semiconductor package.

16. A method for detecting voids in a hybrid bond formed between a first semiconductor package and a second semiconductor package, comprising:
aligning a scanning acoustic microscope with a window in the first semiconductor package, wherein the window comprises a low-density material and is aligned with a hybrid bond formed between a dummy bond pad on the first semiconductor package and a dummy bond pad on the second semiconductor package; and
scanning the hybrid bond formed between the dummy bond pads through the window to detect voids.

17. The method of claim 16, wherein the window extends into the first semiconductor package from a first side of the first semiconductor package, and wherein the dummy bond pad is on a second side of the first semiconductor package.

18. The method of claim 16, wherein the first semiconductor package further comprises a die, and the window extends entirely through the die to contact the dummy bond pad.

19. The method of claim 16, wherein the low-density material has a density of about 0.8 g/cc to about 1 g/cc.

20. The method of claim 16, wherein a third semiconductor package is bonded to the second semiconductor package on a side opposite that of the first semiconductor package, and the second semiconductor package includes a window comprising a low-density material, and wherein the first semiconductor package further comprises a pass-through window that extends entirely through the first semiconductor package and is aligned with the window in the second semiconductor package; and wherein the scanning acoustic microscope is aligned with the window in the second semiconductor package through the pass-through window of the first semiconductor package for scanning a hybrid bond layer formed between the second semiconductor package and the third semiconductor package.
